(19) United States
(12) Patent Application Publication
(10) Pub. No.: US 2006/0267572 A1
(43) Pub. Date: Nov. 30, 2006

(54) Radio frequency identification label and method of labeling

(76) Inventor: Neil G. Sellars, Cinnaminson, NJ (US)

Correspondence Address: REED SMITH LLP, 2500 One Liberty Place, 1650 Market Street, Philadelphia, PA, 19103-7301, US

(21) Appl. No.: 11/367,011

(22) Filed: Mar. 1, 2006

Related U.S. Application Data
(63) Continuation-in-part of application No. 10/634,442, filed on Aug. 5, 2003.
(63) Continuation-in-part of application No. 10/744,581, filed on Dec. 23, 2003.
(60) Provisional application No. 60/657,690, filed on Mar. 1, 2005.

(51) Int. Cl. G01R 25/06

(52) U.S. Cl. 324/90

(57) ABSTRACT

A label, a method of providing a label, and a method of applying a label are disclosed. The label and methods provide a permanently adhering base label portion, semi-permanently affix a removable portion of a secondary label portion at least to at least a portion of the base layer label, permanently affix a non-removable portion of a secondary label portion to a at least a portion of the base layer label, and apply at least a portion of an RF ID tag to a non-external face of the removable portion.

### RELATED APPLICATIONS

This application claims priority of U.S. Patent Application Ser. No. 60/657,690, filed Mar. 1, 2005, and is a continuation-in-part of application Ser. No. 10/634,442, filed Aug. 5, 2003 entitled ‘Extended Wrap Label’, and of application Ser. No. 10/744,581, filed Dec. 23, 2003 entitled ‘Labels And Method Of Making Same’, the entire disclosures of which are each hereby included by reference as if being set forth herein in their entireties, respectively.

### FIELD OF THE INVENTION

The invention relates to labels, and, more particularly, to a radio frequency identifying label and method of making and using same.

### BACKGROUND OF THE INVENTION

Labels, typically in the form of flexible sheet or web material attached to an object, have long been used to identify the object, its contents and/or display other information associated with the object. Such labels, which are normally fabricated from paper or plastic, are usually adhesively secured to the object by a contact or pressure sensitive adhesive material.

A label is oftentimes sufficient to convey desired advertising, content information, instructions, warnings, and the like. In many circumstances, however, an object's physical dimensions detrimentally limit the available print space of, or the availability to place print on, the label borne thereby. Such limits can oftentimes interfere not only with informing the end consumer, but can also limit the abilities of the manufacturers and distributors in providing proper tracking and handling of the labeled object.

Therefore, in addition to the structural features of labels, the label must be suitable for transmitting information not only to the final customer, but also to manufacturers and those involved in the distribution chain. For example, in the case of a pharmaceutical product, the label must not only present product and safety information, but must also contain shipping and shelving information, such as expiration dates and barcoding. However, such features typically used for purposes of shipping, shelving and tracking do not take full advantage of the ever advancing features of computerized systems and networks that streamline information transfer, reduce human error, and that can provide advanced security and tracking.

The details of the present invention in overcoming the aforementioned limitations of the prior art will become apparent as the following description of the embodiments of the invention proceeds.

### SUMMARY OF THE INVENTION

The present invention includes a label, a method of providing a label, and a method of applying a label, wherein the label and the methods include, but are not limited to, numerous different label types, including permanent labels, multi-layer labels, semi-permanent labels, security labels, tamper-evidencing labels, booklet labels, and the like, and wherein the label and methods provide a permanently adhering base label portion, semi-permanently affix a removable portion of a secondary label portion at least to at least a portion of the base layer label, permanently affix a non-removable portion of a secondary label portion to a at least a portion of the base layer label, and apply at least a portion of an RF ID tag to a non-external face of the removable portion.

The present invention operates advantageously to encompass the ever advancing features of computerized systems and networks in that it streamlines information transfer, reduces human error, and provides advanced security and tracking.

### DESCRIPTION OF THE FIGURES

Understanding of the present invention will be facilitated by consideration of the following detailed description of the preferred embodiments of the present invention taken in conjunction with the accompanying drawings, in which like numerals refer to like parts:

FIG. 1 is a perspective view of a conventional wrap-type label affixed to a product container;

FIG. 2 is a top plan view of a first embodiment of a label constructed in accordance with the present invention;

FIG. 3 is a top plan view of a further embodiment of a label constructed in accordance with the present invention;

FIG. 4 is a top plan view of a further embodiment of a label constructed in accordance with the present invention;

FIG. 5 is a perspective view of a label according to the present invention with a releasable end thereof lifted from the surface of a product container to which the label is affixed;

FIG. 6 is a perspective view of the label of FIG. 5 with the releasable end thereof attached to the surface of the product container to which the label is affixed;

FIGS. 7, 8 and 9 are top plan views of labels according to the present invention including means for facilitating separation of a second portion of the label from a first portion thereof;

FIG. 10 is a top plan view of a further embodiment of a label constructed according to the present invention having a tear strip;

FIG. 11 is a perspective view of the label of FIG. 10 shown wrapped about the circumference of a substantially cylindrical product container;

FIG. 12 is a perspective view similar to FIG. 11 with said tear strip removed;

FIG. 13 is a schematic depicting a method for making the labels of this invention;

FIG. 14 is a schematic depicting a further method for making the labels of this invention;

FIG. 15 is a schematic depicting yet a further method for making the labels of this invention;

FIG. 16 is a schematic depicting yet another method for making the labels of this invention;

FIG. 17 is a schematic depicting another method for making the labels of this invention;

FIG. 18 is a top plan view of a further embodiment of a label constructed in accordance with the present invention;

FIG. 19 is a pictorial view, in perspective, of a label assembly in accordance with the invention;

FIG. 20 is a cross-sectional view taken along the line 2-2 in FIG. 19;

FIG. 21 is a cross-sectional view of a form of label in accordance with the invention;

FIG. 22 is a cross-sectional view of another form of label in accordance with the invention;

FIG. 23 is a top plan view, in cross-section, of an exemplary label in accordance with the invention, applied to a substrate in the form of a flat-sided container with small radius corners;

FIG. 24 is a top plan view similar to FIG. 23, also in cross-section, of another exemplary label in accordance with the invention, applied to a substrate in the form of a container of round cross-section;

FIG. 25 is a plan view of a brochure blank for use in the invention;

FIG. 26 is a plan view of a brochure blank for use in an alternative form of the invention;

FIG. 27 depicts a portion of a base label web as used in the invention;

FIG. 28 depicts a base label web, die cut prior to stripping waste, to provide intermediate blanks for base labels in accordance with the invention;

FIG. 29 depicts an alternative form of base label web;

FIG. 30 is a plan view illustrating a brochure blank assembly associated with a base label web in accordance with the invention;

FIG. 31 is a view similar to FIG. 30, illustrating the step of die cutting to produce finished labels;

FIG. 32 is a detail view of a portion of a label in accordance with the invention;

FIG. 33 is a cross-sectional view of yet another form of label in accordance with the invention;

FIG. 34 is a pictorial view, in perspective, of another form of the label assembly in accordance with the invention;

FIG. 35 is a cross-sectional view taken along the line 15-15 in FIG. 34 of a label of this invention in a closed position;

FIG. 36 is a cross-sectional view taken along the line 15-15 in FIG. 34 of a label of this invention in an open position;

FIG. 37 is a detail view of a portion of the label of FIG. 34;

FIG. 38 is a plan view of a brochure blank for use with the label of FIG. 34;

FIG. 39 depicts a base label web, die cut prior to stripping waste, to provide intermediate blanks for base labels in accordance with the invention;

FIG. 40 is a plan view illustrating the brochure blank assembly associated with the base label web in accordance with the label of FIG. 34;

FIG. 41 illustrates a container having thereon a base layer and a secondary label portion having an RF ID; and

FIG. 42 illustrates a container having thereon a base layer and a secondary label portion having an RF ID.

### DETAILED DESCRIPTION OF THE INVENTION

It is to be understood that the figures and descriptions of the present invention have been simplified to illustrate elements that are relevant for a clear understanding of the present invention, while eliminating, for the purpose of clarity, many other elements found in a typical label and labeling method and system. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

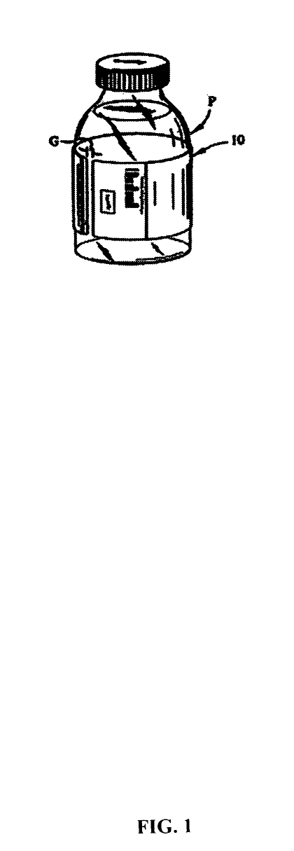

Referring to FIG. 1, there is shown an object, such as a bottle, jar, or any other sort of container, generally referred to herein as container P. Adhesively affixed about the periphery or circumferential side wall of container P may be a wrap-type label 10. Label 10, as is conventional, may cover any fraction of the periphery or circumferential side wall of container P. As illustrated, label 10 may be constructed as an elongated strip member spanning nearly the entire periphery or circumference of container P, and the ends of the label may be separated by a gap G.

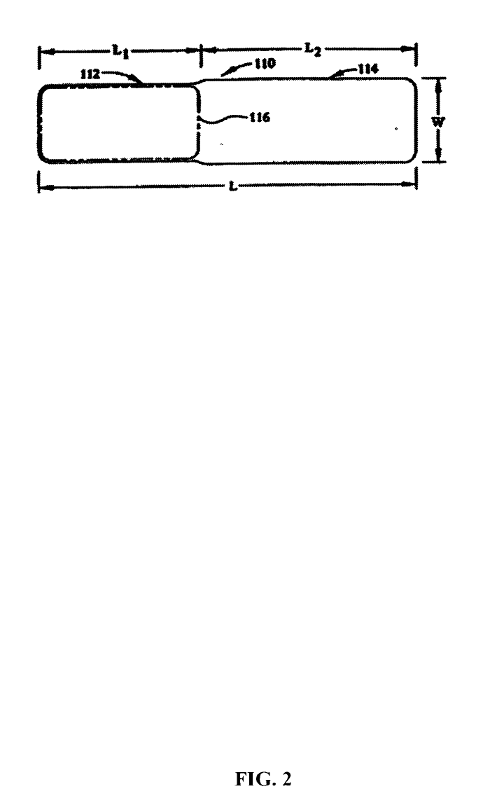

FIGS. 2, 3 and 4 depict several embodiments of labels which may alleviate the problem of limited print space associated with conventional wrap labels similar to label 10 of FIG. 1. Furthermore, labels constructed in accordance with the present invention may incorporate structural features which impart additional functions and advantages to the label.

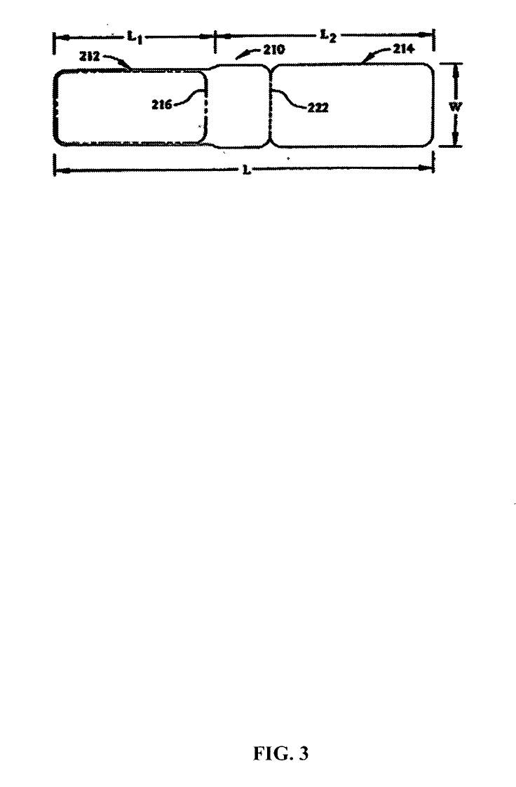

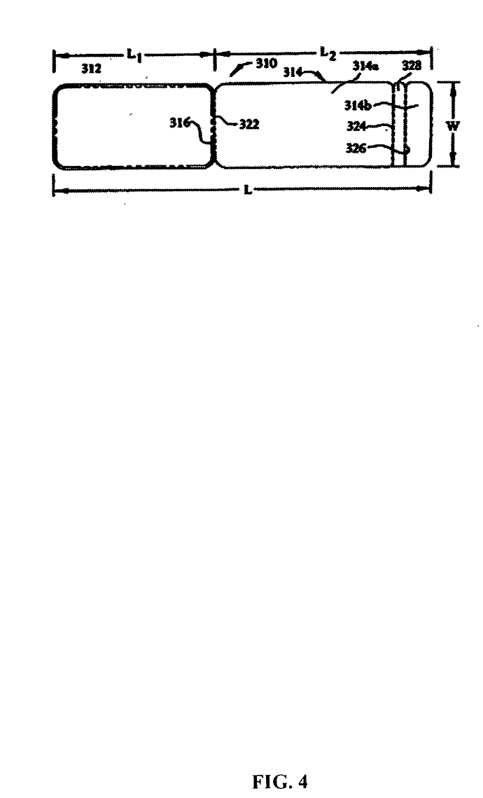

The labels according to the present invention, respectively identified by reference numeral 110 in FIG. 2, 210 in FIGS. 3 and 310 in FIG. 4, include several common characteristic features. For example, each may be comprised of a flexible and printable substrate, such as paper, plastic or web material. Although they may be made individually, the labels may be produced from rolls of such substrates, such as paper or plastic sheet stock which may be continuously printed, coated with adhesive, applied with protective material, affixed to release paper, and cut to produce multiple labels as further described herein. Additionally, each label has an area with general dimensions L and W, which represent the length and width dimensions, respectively, of the label. Length L may be a predetermined distance related to the circumferential dimension of the object to be labeled and width W may be that dimension extending perpendicularly to length L. Width W may vary, as may be desired or necessary, along length L.

As used herein, the terms “circumferential,” “circumference,” or variants thereof shall be construed to include any distance circumscribing the perimeter of the target object to be labeled, regardless of the shape of the object. For example, the object may comprise a polygonal shape (e.g., square or rectangular), curvilinear shape (e.g., circular or oval) or composite polygonal and curvilinear cross-sectional configuration defining a desired perimetrical exterior wall surface to be covered by label 110, 210, 310, 410, 510, 610, 710 or any other label disclosed herein.

Labels 110, 210 and 310 may each include a first portion 112, 212 and 312, respectively, having a length L₁. L₁ may be less than or equal to the circumferential dimension of the object to be labeled. In addition, labels 110, 210 and 310 may include second portions 114, 214 and 314, respectively, of length L₂, which may be contiguous with first portions 112, 212 and 312. Second label portions 114, 214 and 314 provide additional length to first label portions 112, 212 and 312, such that the total length L of labels 110, 210 and 310 may be greater than the circumference of the object to be labeled. All or a portion of the underside of first label portions 112, 212 and 312 may be coated with a layer of pressure sensitive or other adhesive having sufficient tackiness to essentially affix the label on the target object, such adhesive being respectively identified by dot-dash lines 116, 216 and 316.

Each of second label portions 114, 214 and 314 may provide additional print space to labels 110, 210 and 310. Thus, both the top and bottom surfaces of the second label portions may be available as printable surfaces. Depending on which of certain other structural features, as described below, are incorporated into the label of the present invention, second label portions 114, 214 and 314 may also function, without limitation, as resealable and/or removable flaps.

The length L₂ of second portions 114, 214 and 314 may be dictated by, inter alia, the need for additional print space. The label may therefore include any number of wraps of the second label portion about the target object.

Referring more specifically to FIGS. 2, 3 and 4, in FIG. 2 label 110 may comprise first and second portions 112, 114 which may be contiguous regions of an elongated unitary strip of material. No perforation need exist between first and second label portions 112 and 114, though such perforations may still be present in alternative embodiments. Physical demarcation between first label portion 112 and second label portion may be established by the rightmost edge of the pressure sensitive adhesive 116 underlying first portion 112. The boundary between the first and second label portions 112 and 114 may also be distinguished by a change in width W and/or the printed image carried on the label.

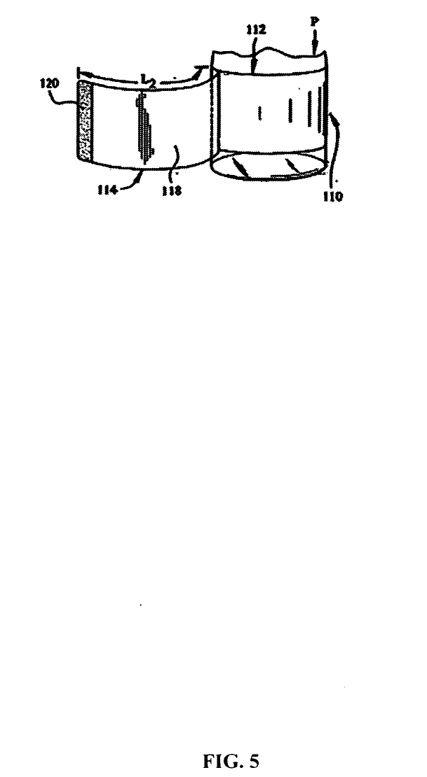

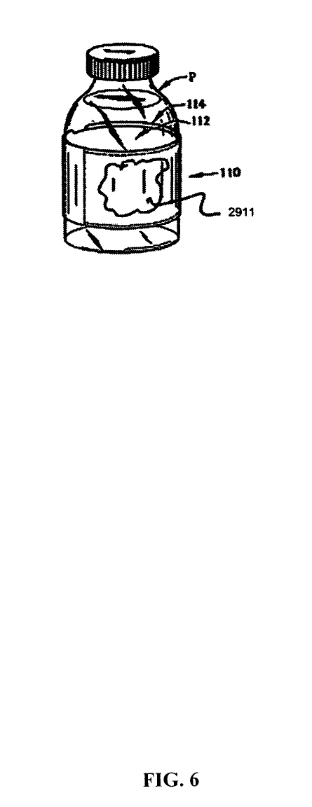

FIGS. 5 and 6 are sequential views of the label 110 being applied to an object such as, for example, a product container P. Referring initially to FIG. 5, first label portion 112 of label 110 is shown wrapped about and adhered to the circumference of container P, and second label portion 114 is depicted in a lifted and turned-away disposition so as to expose the bottom surface 118 thereof. Both the top and bottom surfaces of second portion 114 may be available as printable surface areas. To enhance the utility of label 110, a comparatively narrow strip of tack adhesive material 120 may be provided along the distal edge of the bottom surface 118 of the second label portion 114. Alternatively, tack adhesive 120 may be applied in any pattern and to any area of bottom surface 118 of second portion 114 and to as much as the entire bottom surface 118. The tackiness of adhesive material 120 should be such that it may enable the second label portion 114 to be selectively and repeatedly adhered to the first label portion 112 substantially in the manner shown in FIG. 6, and released from the first label portion as in FIG. 5 to expose the bottom surface 118 of second label portion 114, at the end user's discretion. Where the strip of tack adhesive 120 is employed, the label stock may be coated with adhesive to enable the strip to releasably adhere to the top surface of the first label portion.

Although second label portion 114 may be of any length, an example best illustrates the degree to which a second label portion 114 of relatively moderate length may increase the available print surface area of label 110. Assuming that product container P is a generally cylindrical jar or bottle such as in FIGS. 5 and 6, length L₁ of the first portion 112 of label 110 is selected to be substantially equal to that of the circumference of container P. Recalling that both the top and bottom surface of the second label portion 114 may be printed, if the length L₂ of the second portion 114 is chosen so as to extend for an additional 360° of arc about the circumference of container P, then the total available print surface area may be increased by 200% as compared to the available print surface area of conventional 360° wrap labels. That is, 720° of additional printable surface area may be created in a label which consists of no more than two superimposed layers wrapped about container P. As a consequence, a compact, low-bulk and low thickness resultant label construction may be produced, and may offer essentially three times the print area of a presently existing wrap label such as label 10 of FIG. 1.

FIG. 3 represents a further embodiment of the present invention. According to FIG. 3, label 210 may include a perforation 222 which may be placed at, or, as illustrated, near the boundary between first label portion 212 and second label portion 214. Although not illustrated, second label portion 214 may also include a thin strip of tack adhesive on the bottom surface and at the distal end thereof similar to adhesive material 120 of label 110 (FIG. 5) or in any pattern or to any area of the bottom surface of the second portion. So disposed, the tack adhesive may serve to retain second label portion 214 in contact with first label portion 212 until deployment of the second label position is desired. In this way, some or all of second label portion 214 may be torn from first label portion 212 along perforation 222 to expose the surface of the first label portion previously covered by the second label portion. Additionally, the second label portion may be adapted for a use when detached from the first label portion that may be independent of the function of the first label portion. For example, second label portion 214 may be printed with information such that it may function as a redeemable coupon for consumer merchandise.

In FIG. 4, label 310 may include a perforation 322 generally at or near the boundary between first label portion 312 and second label portion 314. Additionally, second label portion 314 may be provided with a pair of comparatively closely spaced perforations 324 and 326 disposed adjacent the end of second label portion 314 opposite first label portion 312. Perforations 324, 326 together may define a removable tear strip 328, described below, which may separate second label portion 314 into a first, non-adhesive-bearing, removable segment 314a and a second adhesive-bearing segment 314b. Alternatively, a single perforation may be located in second label portion 314 in order to separate second label portion 314 from segment 314b.

The bottom surface of the second label segment 314b may be coated with a pressure sensitive or other adhesive (not illustrated) similar to adhesive 316 as provided on first label portion 312. In this way, when label 310 is fully wrapped about an object, such as product container P shown in FIGS. 1, 5 and 6, the first label portion 312 may be essentially affixed to the circumferential wall of the container and the second segment 314b of the second label portion 314 may be similarly affixed to the first label portion 312. Alternatively, if L₂ is greater than the circumference of container P, second segment 314b of second label portion 314 may be affixed to second label portion 314.

As shown in FIG. 4, in order to detach the first removable segment 314a, the end user may simply grasp and pull the tear strip 328 (which alternatively may or may not have adhesive on its bottom surface), thereby severing the tear strip from the first and second segments 314a, 314b along perforations 324, 326. Thereafter, the user may grasp and pull the first segment 314a to sever it from the first label portion 312 along perforation 322. At this stage, the area of the first label portion 312, as well as any area of second label portion 314 previously covered by the first label segment 314a of the second label portion 314 may be exposed. Also, the detached first label segment 314 may perform an additional function, for example, as a redeemable coupon, or the like. Additionally, tack adhesive 120 (not shown in FIG. 4) may be added to the bottom surface of segment 314a in a fashion similar to that for labels 110 and 210, in order to provide a resealable means for segment 314a. Further, the first label segment 314 may perform an additional function, for example, as a resealable segment.

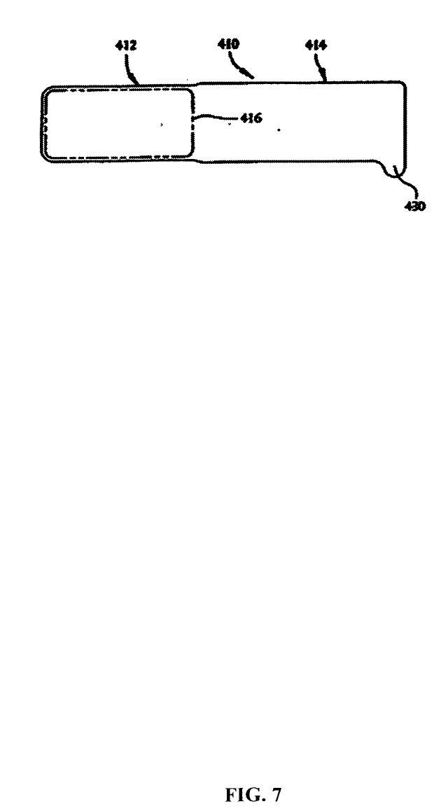

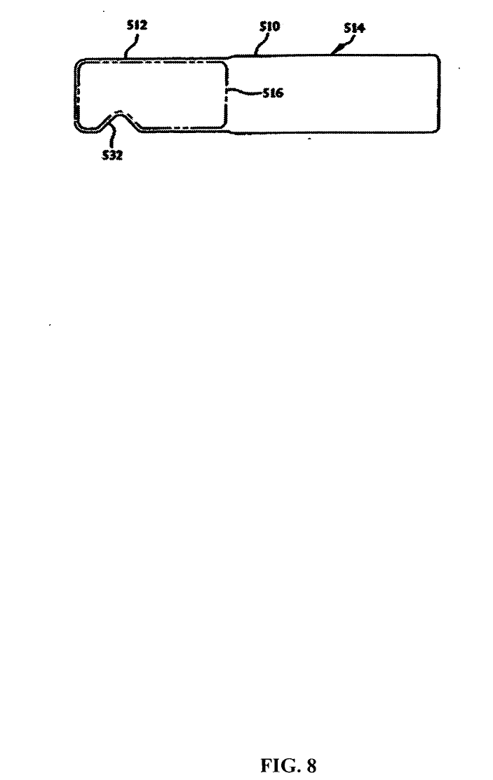

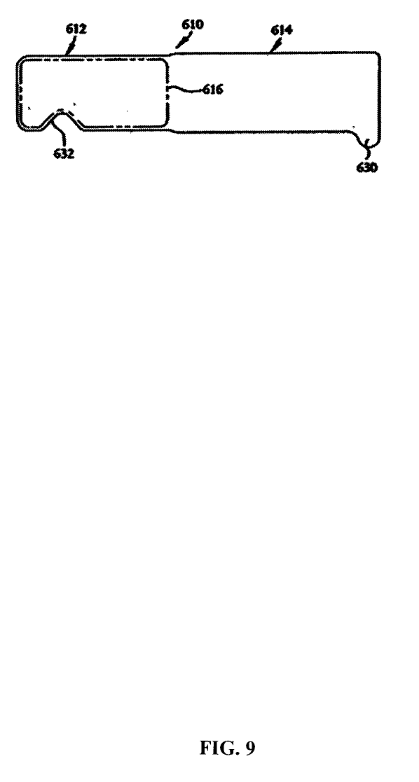

FIGS. 7, 8 and 9 illustrate further embodiments of a label constructed according to the present invention, identified respectively by reference numerals 410, 510 and 610. It should be understood that labels 410, 510 and 610 may be constructed substantially similarly to any of the label embodiments disclosed herein, including, but not limited to, labels 110, 210 and 310 described above, or label 710 as discussed below.

More particularly, labels 410, 510 and 610 may depict exemplary separation of the releasable second portions of the labels from the first portions thereof, when the labels are secured to objects, such as products or product containers. These means may include a protrusion 430 provided adjacent to a distal end of the second portion 414 of label 410, a notch 532 adjacent to an end of the first portion 512 of label 510, or a combination of a notch 630 adjacent to a distal end of second portion 614 and a notch 632 adjacent to an end of the first portion 612 of label 610. Each of these means may enable easier insertion of a user's finger or fingernail beneath the releasable second portion of any of the labels herein described when such labels are affixed to a product or product container whereby the second label portion may be more easily lifted and separated from contact with the first label portion.

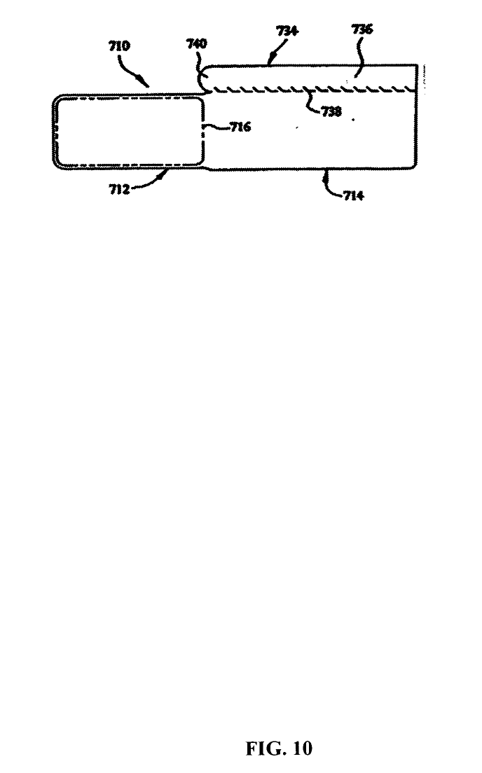

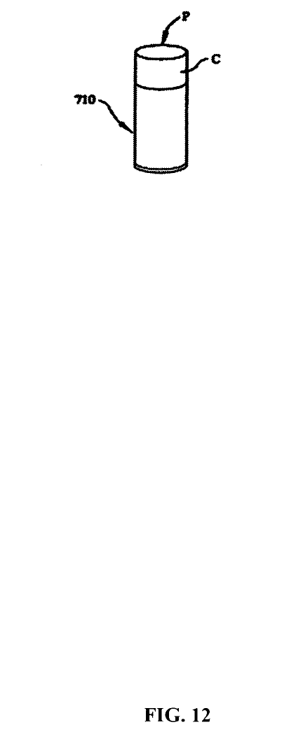

FIGS. 10, 11 and 12 reveal a further embodiment of a label 710 constructed in accordance with the present invention. Label 710 may be manufactured in a substantially similar manner to and/or may incorporate any combination of the features of previously described labels 110 through 610. Label 710 may include means 734 for evidencing tampering of product prior to any consumption thereof by an end user. In addition to the tampering means discussed in these exemplary embodiments, it will be apparent to those skilled in the art in light of the disclosure herein that any tampering means may be operable with the present invention. In one embodiment of the present invention, tamper evident means 734 may comprise a fixed or disposable tear strip 736 contiguous with either the first, the first and second, or, as shown, the second portion 714 of label 710 along perforation 738. Tear strip 736 may be of any length, though typically may correspond to the length of the circumference of C as shown in FIG. 12.

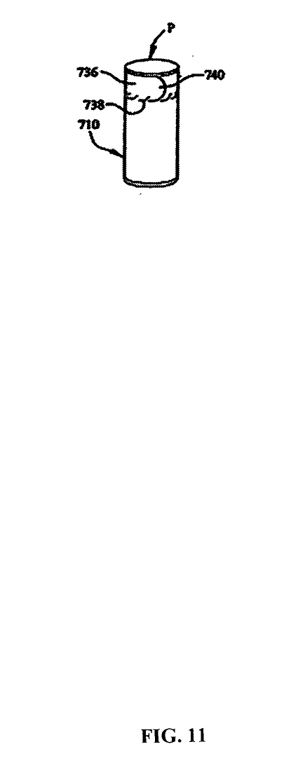

FIG. 11 shows label 710 as it would appear when affixed to the circumferential side wall of a substantially cylindrical product container P. To assure its attachment to the product container prior to removal, all or a portion of the tear strip 736 may be provided with a pressure sensitive or other suitable adhesive. When it is desired to access the contents of container P, the end user may simply lift a distal end flap 740 of the tear strip 736 and pull the strip away from the remainder of the label 710 such that the strip detaches from the label along perforation 738. Upon removal, the tear strip may be discarded.

Once tear strip 736 is removed, the product container cap or lid C may be exposed, thereby enabling the user to remove the cap and access the contents of the product container P. However, should the end user discover that, prior to purchase or use, tear strip 736 is missing or damaged, tamper evident means 734 may alert the user that consumption of the contents of product container P should be avoided.

Alternatively, distal end flap 740 may be omitted from tear strip 736. Tear strip 736 may be temporarily or permanently affixed to cap C, and instead of the end user tearing away tear strip 736, the end user may remove cap C by twisting or pulling, thereby breaking perforation 738 and alerting a subsequent user that the container had been previously opened or otherwise tampered with. In this embodiment, tear strip 736 may either be removed from or remain attached to cap C.

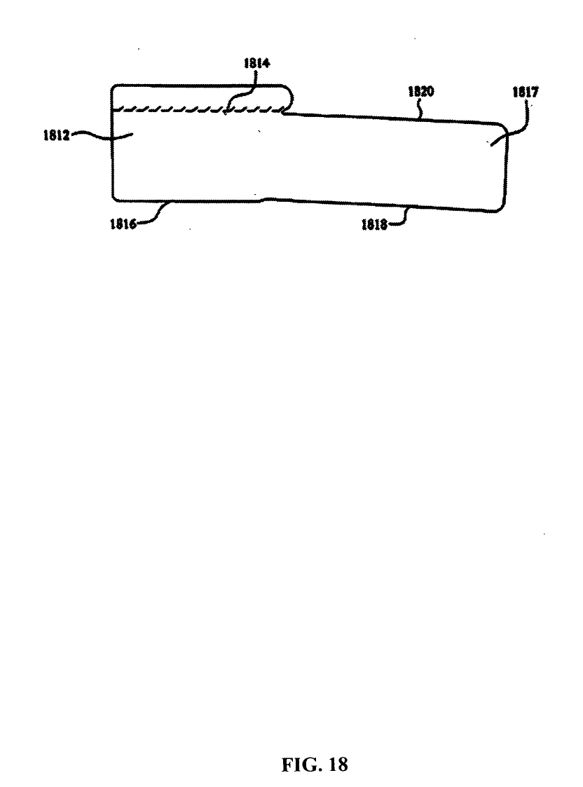

Referring now to FIG. 18, there is shown a product label 1800 constructed in accordance with the present invention. Label 1800 is essentially identical to the label shown in FIG. 10, except that label 1800 may be adapted for application to irregularly shaped objects, such as, for example, tapered objects. However, as is the case with any of the exemplary labels discussed hereinthroughout, the additional features of label 1800 may be applied to any of the labels of the present invention as described herein. Label 1800 may have a first portion 1812 with a top edge 1814 and a bottom edge 1816. The label 1800 may also have a second portion 1817 with a top edge 1818 and a bottom edge 1820. To accommodate application to a tapered object having a top with a larger circumference than the bottom, the top edges 1814 and 1820 may be longer than the corresponding bottom edges 1816 and 1818. In addition, the first portion 1812 may be oriented at an oblique angle relative to the second portion 1817. The relative length of the top and bottom edges and the angle between the first and second portions depend upon the shape and size of the article to which the label is to be applied. Generally, the greater the taper of the article, the greater the angle and the greater the difference between the length of the top and bottom edges, and vice versa. The specific lengths and angle may be selected so that the second portion 1817 substantially precisely overlaps the first portion 1812 when the label 1800 is wrapped more than 360° around an article. Alternatively, the specific lengths and angle may be selected so that the second portion 1817 only partially overlaps the first portion 1812 and partially contacts the container when label 1800 is wrapped more than 360° around an article. Some or all of the edges may be curved to accommodate the difference in length between the top edges and the bottom edges. In FIG. 18, the top edge 1820 of the second portion 1817 may be curved. In another alternative embodiment, the second portion may comprise one or more sub-sections, wherein each sub-section may be at an angle relative to the adjacent preceding sub-section and the angle may be selected to fit the geometry of the object to which the label is to be applied.

As mentioned above, the label(s) of the present invention as discussed hereinthroughout may be comprised of a flexible and printable substrate such as paper or plastic (such as, for example, polyvinyl chloride, polyethylene or polypropylene) sheet or web material. Although each label may be made individually, labels are preferably produced in larger quantities from rolls of such substrate, such as sheet stock which can be continuously printed, coated with adhesive, affixed to release paper, and cut to produce multiple labels. One or more areas or surfaces of the label may also be coated with a lacquer or varnish in order to protect the label and/or printed inks from wear or other degradation.

Also, as an alternative to the protective lacquer or varnish, an additional layer of protective material (for example, a substantial transparent layer of plastic such as polyvinyl chloride, polyethylene or polypropylene) may be applied to select surfaces or areas of the label. The means by which the labels will be made will depend, in part, upon the features which are to be incorporated into such labels.

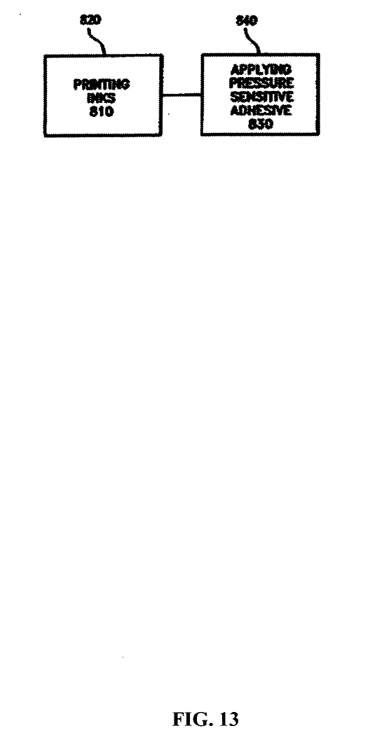

Referring to FIG. 13, there is shown a schematic depicting a method for making labels. It should be noted at the outset that the order in which the steps of the methods herein disclosed are carried out is not necessarily critical. As mentioned above, the labels are made from a flexible and printable substrate 800. Graphic or other inks 810 may be printed by printing step 820 (for example, by flexographic, rotogravure, silk screening or other printing methods) at predetermined locations on the top and/or bottom surfaces of substrate 800.

For example, depending on the desired or necessary label configuration, inks 810 may be applied to: the top surface of first label portion 112, 212, 312, 412, 512, 612, or 712; the top surface of second label portion 114, 214, 314a, 414, 514, 614, or 714; and/or the bottom surface of second label portion 114, 214, 314, 414, 514, 614, or 714. Pressure sensitive adhesive 830 may be applied by step 840 (e.g. hot melt or other adhesive means) to predetermined locations on the bottom surface of substrate 800 so as to provide a means by which the label may be affixed to the desired object. For example, depending on the desired or necessary label configuration, pressure sensitive adhesive 830 may be applied to the bottom surface of the first label portion 112, 212, 312, 412, 512, 612, or 712.

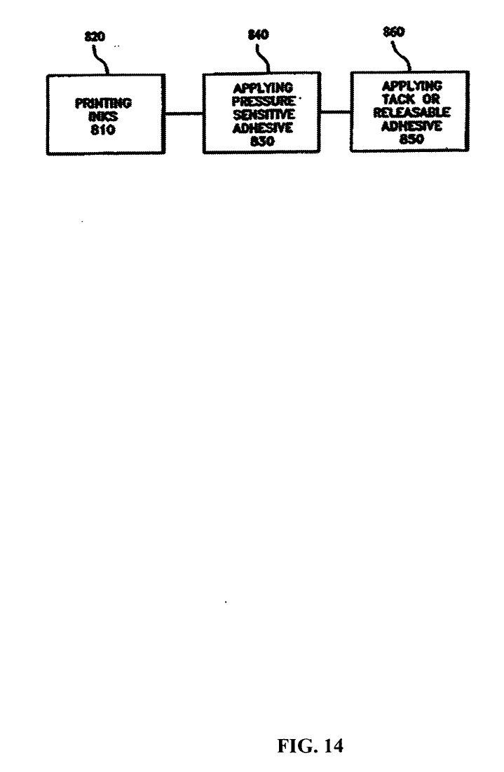

FIG. 14 depicts a method for making the labels of this invention, which adds to the steps shown in FIG. 13 optional step 860 for applying tack or releasable adhesive 850 to select locations on substrate 800, such that the second label portion may be selectively and repeatedly adhered to the first label portion. For example, depending on the desired or necessary label configuration, tack or releasable adhesive 850 may be applied to the distal edge of the bottom surface of first label portion 112 (i.e. 118), 212, 312, 412, 512, 612, or 712.

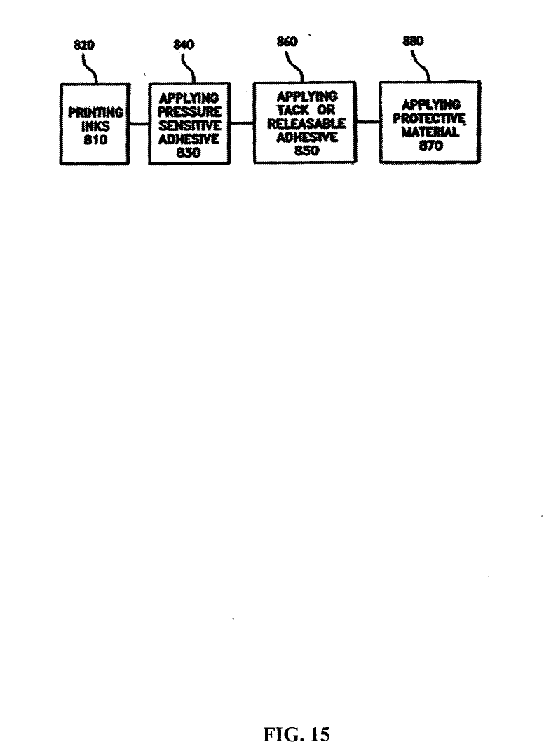

FIG. 15 depicts a method for making the labels of this invention, which may add to the steps shown in FIG. 14 optional step 880 for applying a protective material 870 to select locations over substrate 800 and/or inks 810 in order to protect substrate 800 and/or inks 810 from wear or other degradation. For example, depending on the desired or necessary label configuration, protective material 870 (e.g. lacquer, varnish, PVC, or other substantially transparent protective material) may be applied to any surface. In addition, it should be noted that either adhesive 830 or 850 may be applied over protective material 870, provided that such application does not cause an adverse chemical reaction.

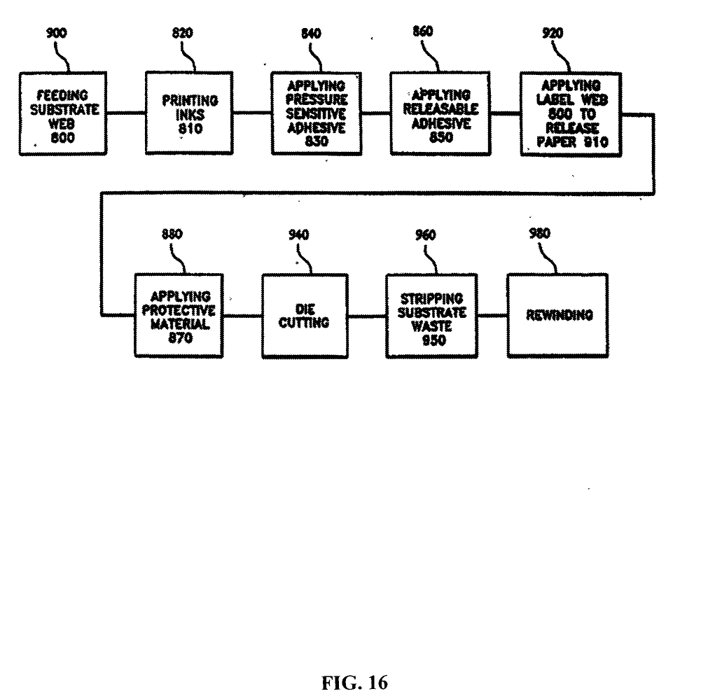

FIG. 16 depicts a method for making the labels of this invention, which may add additional optional steps to the steps shown in FIG. 15. In this embodiment, substrate 800 may be in the form of a web in order to facilitate the production of larger quantities of labels. Specifically, in step 900, substrate web 800 is fed through a series of process steps. Each such step is represented schematically by a box in FIG. 16.

As indicated above, the order in which the steps are carried out is not necessarily critical to the successful manufacture of the labels of the present invention. With this in mind, inks 810 may be printed on one or both sides of web 800 in printing step 820. Pressure sensitive adhesive 830 may be applied to select areas of web 800 in application step 840. Releasable adhesive 850 may be applied to select areas of web 800 in application step 860. A surface of web 800 bearing pressure sensitive adhesive 830 may be applied to release paper 910 in application step 920, such that the resulting labels produced from this process may later be removed for application to container P. In application step 880, protective material 870, which may include any sort of lacquer, varnish or any other at least partially transparent protective material, may be applied to select surfaces of web 800, which surfaces may or may not contain pressure sensitive adhesive 830. In die cutting step 940, substrate web 800 (along with any protective material 870) may be die cut to form label blanks, perforations, and/or other openings (if any) in web 800. In stripping step 960, substrate waste 950 may be removed from release paper 910 after die cutting step 940, thereby leaving finished label blanks releasably adhered to release paper 910 for later application to container P. Finally, in optional rewinding step 980, release paper 910 bearing die cut label blanks may be wound into rolls or other convenient form for later application of the resulting labels to container P or other objects by manual or automated means.

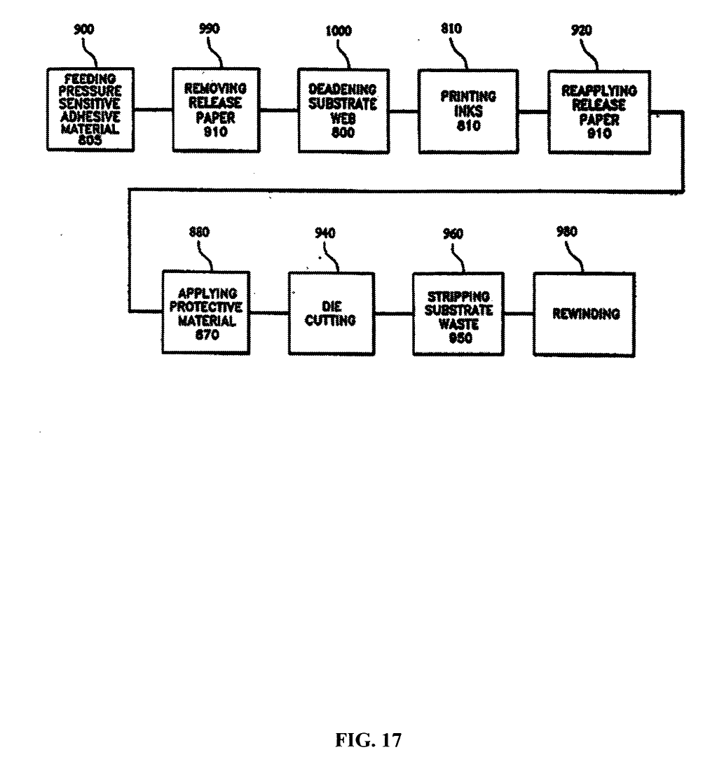

FIG. 17 depicts another method for making the labels of the present invention, which method is similar to the method set forth in FIG. 16, except that substrate web 800 may be replaced with a pressure sensitive adhesive (PSA) material 805. PSA material 805 may comprise substrate web 800 releasably adhered to release paper 910 by pressure sensitive adhesive 830, which adhesive 830 may be typically coated on one side of web 800. In step 900, PSA material 805 may be fed through a series of process steps. Each such step may be represented schematically by a box in FIG. 17. Again, the order in which the steps of this method are carried out is not necessarily critical to the successful manufacture of the labels of this invention. With this in mind, in step 990, release paper 910 may be removed from PSA material 805 to expose pressure sensitive adhesive 830.

As discussed above, in certain embodiments of the labels of the present invention, it may be desirable to have certain portions of the label which are coated with pressure sensitive adhesive 830 (see e.g. portions 116, 216 and 316 of FIGS. 2 through 4, respectively, and portions 416, 516, 616 and 716 of FIGS. 7 through 10, respectively) in certain areas which may be intended to be indicia or ink bearing surfaces (see e.g. second portions 114, 214 and 314 of FIGS. 2 through 4, respectively, and 414, 514, 614 and 714 of FIGS. 7 through 10, respectively). When PSA material 805 is provided with pressure sensitive adhesive 830 in areas where it may be necessary or desirable to print indicia or inks 810, such areas may be “deadened” by either removing pressure sensitive adhesive 830 from web 809, or by applying a detackifying material, such as a varnish, laminate or other material capable of providing a suitable surface for the printing of indicia or inks 810. This deadening process may be particularly useful when it is necessary or desirable to print on the surface of web 800, which surface also bears pressure sensitive adhesive 830 (see e.g. surface 118 of FIG. 5).

The deadening process (if any is required) may be carried out in step 1000. With PSA material 805 prepared, web 800 may be printed with inks 810 on any surface of the label which is suitable for accepting inks 810, Such printed surfaces may include both top and bottom surfaces of the label being produced, any surface not bearing pressure sensitive adhesive 830, or any surface which has been deadened in step 1000. Printing step 810 may comprise one or more steps wherein the top and bottom surfaces of the label may be printed either simultaneously or in separate steps. In one embodiment of the invention, inks 810 may printed on the top surface of the PSA material 805. PSA material 805 may be turned over, and inks 810 may be printed on the bottom surface of PSA material 805.

In step 920, release paper 910 may be reapplied to web 800 with pressure sensitive adhesive 830. Reapplication step 920 may occur at any time after printing step 810 is completed with respect to the surface of the label which also bears pressure sensitive adhesive 830.

As in the method depicted in FIG. 16, application of protective material 870 may take place in step 880, die cutting of individual labels takes place in step 940, substrate waste 950 may be stripped away in step 960, and the resulting web which bears the finished die cut label blanks may be rewound in step 980.

The present invention may also include labels which incorporate brochures or booklets for increasing the printable area of the label. In one embodiment of the present invention, a brochure label may be resealable, that is, so constructed and arranged that opening or use of the brochure associated with the label does not render impossible resealing of the brochure. Thus, a resealable brochure label may be restored to its initial appearance and condition after having been opened. The brochure label may also be capable of neatly wrapping around the sharp or small radius corners of a square container, or any other shaped container. Thus the brochure portion of the present invention may provide for a smooth and highly pleasing wrap for the brochure.

Another desirable attribute in a brochure label may be the ease of opening and reseal-ability. The present invention may provide a simple and effective tab to facilitate opening, as well as capability of repeated resealing.

In some applications, it may be necessary or desirable that the graphics and other aesthetic aspects of the brochure be integrated with those of the products labeled, so as to provide a uniform appearance and appeal. In accordance with the present invention, the printing of the brochure component of a brochure label may be coordinated with that of the base label, using matched or coordinated materials or printing techniques, so that the base label and brochure provide the appearance of a unitary piece.

Finally, in some instances it is desirable that one or more leaves or pages of the brochure may be removable, or that provision be made for removeability of the entire brochure at the user's option. As is explained below, suitable structural features may be provided within the purview of the present invention to achieve these desirable ends.

Labels in accordance with the present invention may be delivered to users in roll form and applied to packages in the same manner, using the same equipment, and at satisfactory production speeds (generally in excess of 200 bottles per minute) as standard pressure sensitive labels.

Generally, the present invention may provide an adhesive label assembly which includes an integral brochure. The assembly may comprise of a pressure sensitive base label, adhesively and releasably supported by a flexible liner. The brochure may be associated with the base label (which may be any label as described throughout), and may be made up of a folded sheet providing panels, or pages, of the brochure. The brochure may be positioned to overlie at least a portion of the base label, and the top panel of the brochure may be made to project laterally beyond a lateral edge of the base label. The projecting portion of the top panel may provide a tab to facilitate opening of the brochure. A self-adhesive transparent overlayer may be provided over the upper surface of the base label and also the top panel of the brochure. The overlayer may be made to extend beyond an edge of the top panel, to facilitate sealing and resealing by adhesion of the overlayer to the container or other substrate to which the base label is applied or to a remote end portion of the base label. Alternatively, sealing and resealing of the overlayer may be accomplished by adhering the extended portion of the overlayer to a portion of the base label which extends beyond a bottom panel of the brochure. Regardless of the specific embodiment of the invention, the top panel may also provide a tab, which, in association with the projecting portion of the overlayer, provides both a means for sealing the brochure and a means for easily gripping the brochure to facilitate opening.

Optionally, perforations may be provided on one or more panels of the brochure, to facilitate ready removal of the page provided by that panel. Those skilled in the art will appreciate that the removed page may be or include a coupon, a premium, or a pre-printed request for additional information.

Optionally and alternatively, a line of perforations may be provided in the base label and overlayer, so that the consumer may remove the booklet without destroying the copy contained on the base label beneath it.

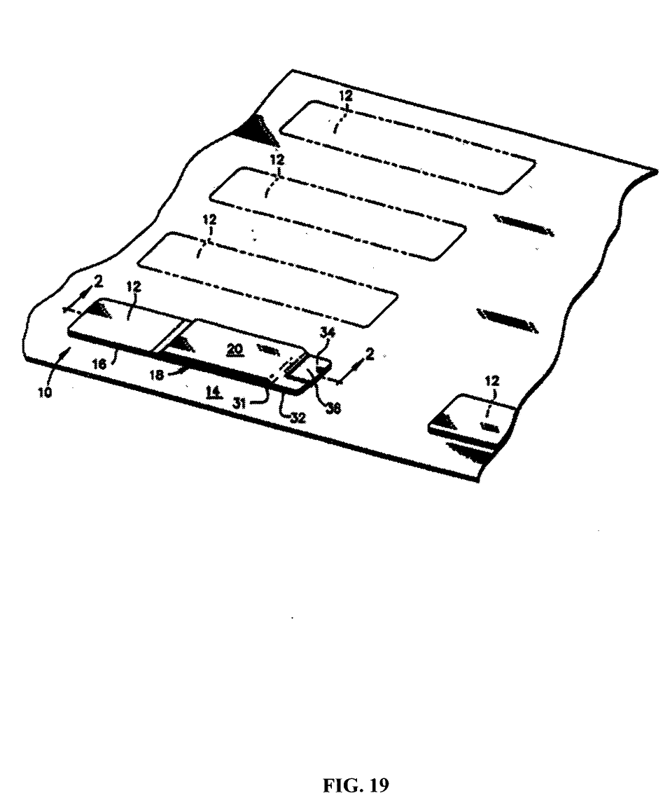

Referring now to FIG. 19 a label assembly is designated generally by the reference numeral 10. The label assembly 10 includes plural individual labels 12, disposed on a flexible liner 14. It should be understood that the thicknesses of the liner 14 and labels 12, as well as the various components which are laminated to make up the label 12, are exaggerated for clarity.

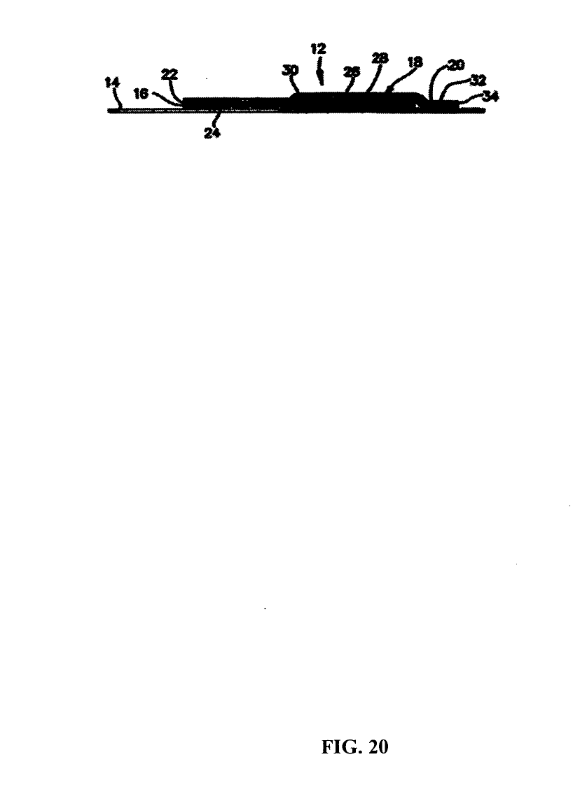

Referring to FIGS. 19 and 20, an individual label 12 will be described in detail. The label 12 includes a base label 16, a brochure 18 and a transparent overlayer 20. Seen in FIG. 20 is an adhesive layer 22 by which the overlayer 20 is secured to the base label and the brochure 18 (and which, in turn, secures the brochure 18 to the base label 16), and an adhesive layer 24 which releasably secures the base label 16 to the liner 14.

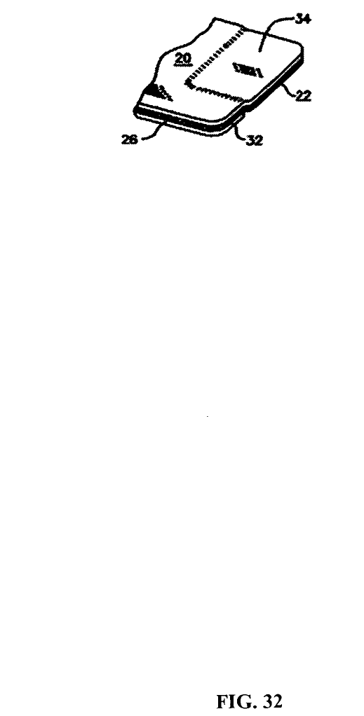

The brochure 18 in FIGS. 19 and 20 may be a leaflet which has two leaves 26 and 28, separated by a fold line 30. The top leaf 26, it will be seen, is wider than the bottom leaf 28, and thus extends further from the fold line 30 than does the bottom leaf 28. A portion of the top leaf 26 extends beyond the lateral edge 31 of the base label 16. As is perhaps best seen in FIG. 19 (and also in FIG. 32), a portion of the top leaf 26 is shaped to provide a tab 32, the purpose of which will be described shortly. As is also apparent in FIG. 19, a portion 34 of the overlayer 20 projects beyond a lateral edge 36 of the top leaf 26 in the vicinity of the tab 32, and is thus adhesively joined directly to the liner 14.

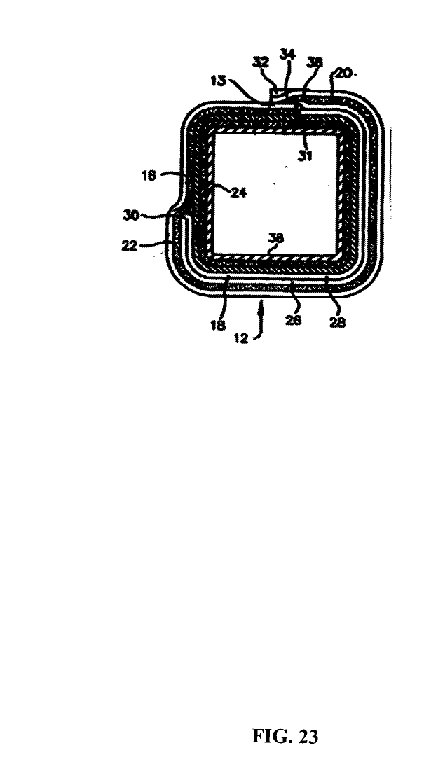

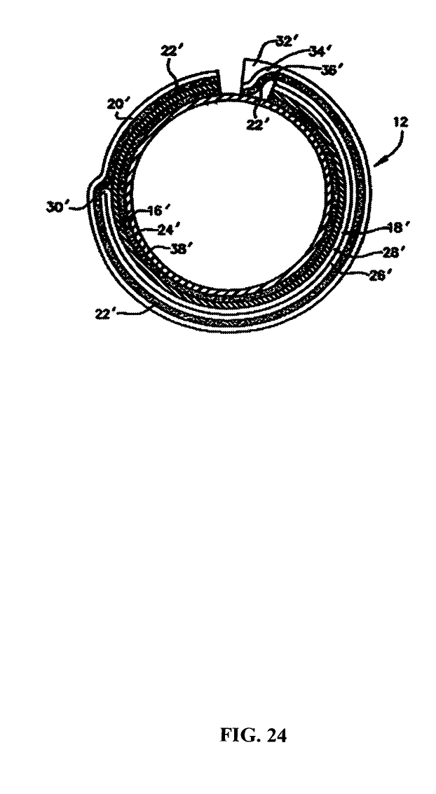

Referring now to FIG. 23, the manner in which a label such as the label 12 may be affixed to a substrate in the form of a container 38 is seen. In the example shown in FIG. 23, the container 38 is a round cornered square container. The label 12 wraps completely around the circumference of the container 38, without any bunching or buckling of the brochure 18 at the corners. This desirable result is achieved because, as described above, the top leaf 26 of the brochure 18 and the portion 34 of the overlayer 20 extend beyond the lateral edge 31 of the base label 16. In such an arrangement, the top leaf 26, with its associated overlayer 20 can be drawn tightly and smoothly during application of the label 12 to the container 38, thus enabling the adhesive 22 of the portion 34 to self-adhere (in the illustrated example) to a terminal portion 13 of the label 12. In other applications, such as the one shown in FIG. 24 (in which elements corresponding to those already described are designated by like, primed (′), reference numerals), the adhesive 22′ of a portion 34′ may adhere directly to a container 38′.

The tab 32 facilitates opening of the brochure, because it is interposed between the adhesive 22, 22′ and, as the case may be, the terminal portion 13 of the label 12 or the container 38′. The tab 32 thus provides a convenient “handle” and an aid to opening of the brochure. On the other hand, the adhesive 22, 22′ on the portions 34, 34′ facilitates repeated resealing of the brochure as the contents of the containers 38, 38′ are used.

It should be understood that the embodiments seen in FIGS. 23 and 24 are illustrative, and that a label applied as shown in FIG. 23 may be used to advantage on a round or otherwise shaped container or substrate, such as the round container 38 shown in FIG. 24. Similarly, a label may be applied as shown in FIG. 24 to a square or rectangular container, such as the container 38 of FIG. 23.

The stock from which the base labels 16 are made has been described in detail above, and is also commercially available and familiar to those skilled in the art. It generally comprises a layer of paper, peelably joined by pressure sensitive adhesive to a liner of flexible plastic polymeric film.

The material for the overlayer 20 is also commercially available, and may comprise a flexible clear plastic polymeric film, coated on one face with a clear pressure sensitive adhesive (which provides the adhesive 22, 22′). The top surface of the overlayer 20 may be treated in a known manner (as by having on it a release agent) to facilitate release and to avoid co-adhesion failure. All or a portion of the base label, the underlayer, or the brochure pages may be treated with the reactive varnish, and may be activated as discussed hereinabove. In a preferred embodiment the treatment with reactive varnish may occur in such a way as to not unintentionally seal the overlayer or the pages together or to the base layer.

In still another of its aspects, the invention provides a method of making an adhesive label assembly of the kind having an integral brochure. The method includes steps of: providing a pressure sensitive base label web comprising a base label sheet and a flexible liner releasably secured to the base label sheet; die cutting through the base label sheet but not the liner to form a blank for at least one and preferably two or more base labels; and stripping from the liner the material of the base label sheet other than the blank. Next, a brochure blank assembly, printed to provide multiple brochures, may be mated to the base label web and so positioned that a top panel of the assembly projects laterally beyond what will be the lateral edge of the base label. Alternatively, at least a portion of the base label may also extend beyond a bottom panel of the brochure. Next, there may be applied over the liner, brochure blank assembly and base label an overlayer of self-adhesive material, the self-adhesive material serving to secure the brochure blank assembly to the base label blank and also adhering to the liner adjacent to the tab portion. Alternatively, where the base label extends beyond the bottom panel of the brochure, the overlayer self-adhesive material may serve to secure the brochure blank assembly to the base label and also adhere to the extended portion of the base label.

Optionally, brochure blank assembly may be affixed to the base label by a suitable adhesive or by other affixation means. Die cutting through the overlayer and stripping of the waste yields the desired label assembly, with the individual labels releasably secured to the flexible liner.

Referring now to FIGS. 19 and 25-31, a method of making an adhesive label assembly in accordance with the invention will be described.

The brochure blank assembly may be prepared in full web width. A base label may be printed, also in full web width. Next, the base label may be die cut from a base label web 42, and excess may be stripped to base label blanks, each blank ultimately providing, in the presently preferred form of the method, two base labels. Next, the brochure blank assembly 40 may be brought together with the die cut and stripped base label web, and a pressure sensitive overlayer 20 may be applied over the exposed liner 14, the base label and brochure blank assembly, joining in the process the base label and brochure. No glue is necessary to assemble the base label and brochure, although glue may optionally be used in some embodiments. Finally, the assembled base label, brochure and overlayer may be die cut to the final outline of the label, and waste may be stripped to yield the final label assembly.

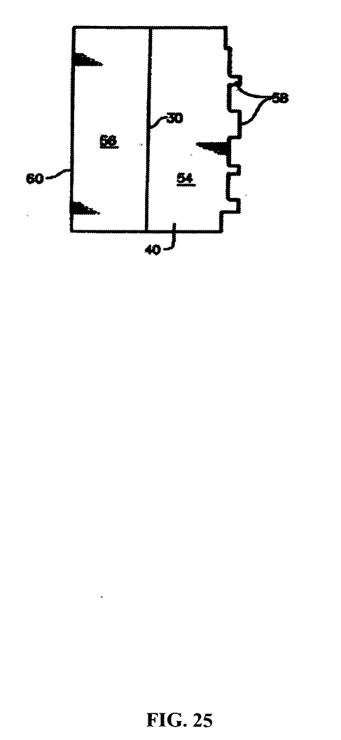

Referring now to FIG. 25, the brochure is printed by any suitable process, in the presently preferred process by sheet-fed offset printing in full web width (typically about twelve inches). Each sheet may contain multiple repetitions width wise. One presently preferred form of the process prints four wide. The portions of the blank assembly 40 which, with further trimming, may ultimately form the above-mentioned tabs 32, may be die cut, although other techniques may occur to those skilled in the art. The sheet may then be trimmed to size and folded as desired, as at fold line 30 in FIG. 25.

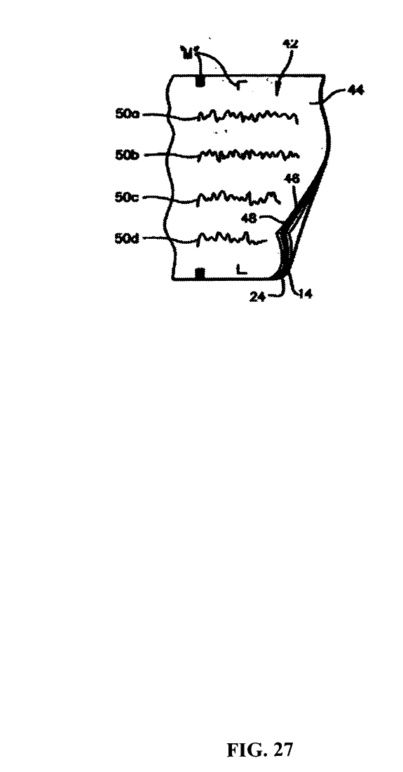

Referring now to FIG. 27, a base label web, designated generally by the reference numeral 42, a portion of which is seen in the Figure, is provided. The base label web is comprised of a base label sheet 44, of paper or other suitable material and liner 14 releasably adhered to the base label sheet 42. The base label web 42 has respective lower 46 and upper 48 faces, and has on its lower face a continuous layer 24 of adhesive which provides the above-mentioned adhesive layer 24 in the finished product. Printed matter suitable to the intended finished product may be applied to the upper face 48 of the base label sheet 44 by any suitable printing process. Suitable eye and machine-readable positioning, “eye” and registration marks “M” may also be printed on the base label sheet 44, to facilitate joining of the brochure blank assembly 40 with the base label web 42 (as described below) and other automated process steps. As is apparent in FIG. 27, printing of the base label sheet 44 may be done in full web width, providing multiple repetitions across the width of the web. The illustrated example provides four repetitions designated in the Figure as 50a-d.

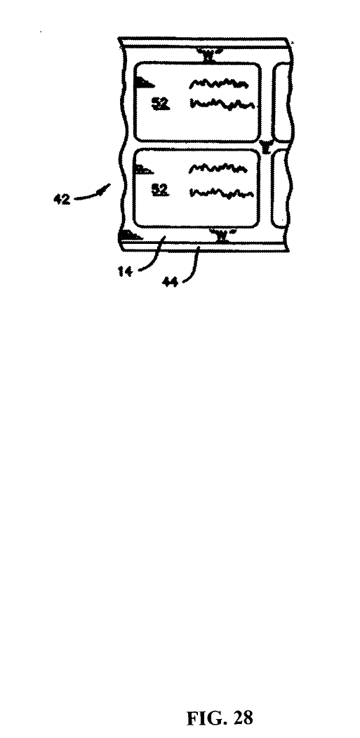

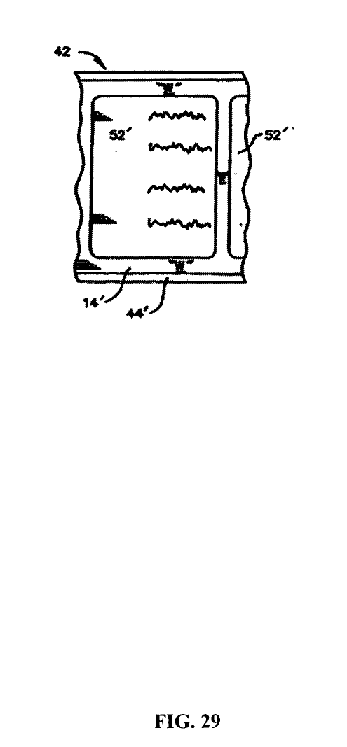

FIGS. 28 and 29 depict alternative forms of the base label web 42 after die cutting through the base label sheet 44 (but not the liner 14) to form base label blanks 52. In FIG. 28, the die cutting operation may provide two base label blanks 52, the width of each blank 52 enabling it to provide a base label 16 (FIG. 19) for two labels 12. In the alternative arrangement shown in FIG. 29, a single base label blank 52′ may be provided, of a width enabling it to provide a base label 16 for four labels 12. Other equivalent arrangements may occur to those skilled in the art. After die cutting, waste material “W” around the base label blanks may be stripped from the base label web 42.

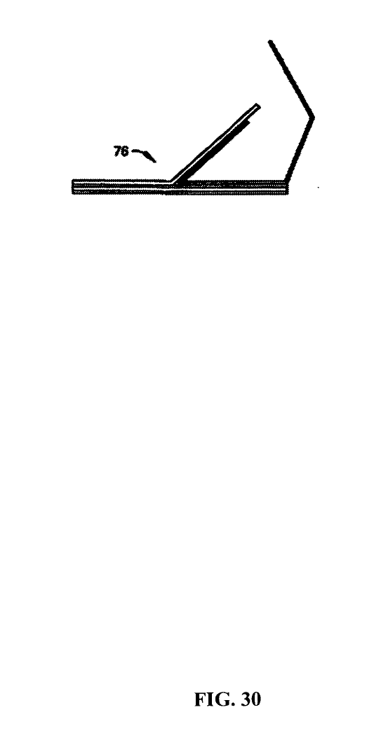

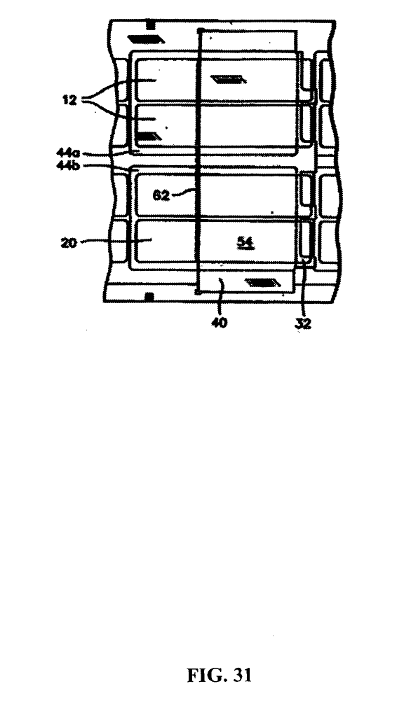

Referring now to FIGS. 30 and 31, the step of joining the brochure blank assembly 40 with the base label web 42 is illustrated. As is best seen in FIG. 30, the brochure blank assembly 40 may be brought into juxtaposition with the base label web 42 in such a way that the fold 30 extends transversely with respect to the base label sheet 44. It may be recognized that this operation may be automated in ways familiar to those skilled in the art, drawing brochure blank assemblies 40, for example, from a hopper (not seen) and synchronizing the application of brochure blank assemblies 40 to a moving base label web 42. Folding of the brochure blank 40 may be done in such a way as to provide an assembly having a top panel 54, which ultimately forms the above-mentioned top leaves 26 of the brochures 18, and a bottom panel 56, which may ultimately form the bottom leaves 28 of the brochure 18. Associated with the top panel 54 may be projections 58 which, after further cutting described below, may form the tabs 32 associated with the top leaves 26. The top panel 54, it should be understood, may extend from the fold line 30 a distance greater than the width of the bottom panel 56, so that when the brochure blank assembly 40 is positioned with respect to the base label web 42, the panel 54 may project beyond a lateral edge 60 of what will become the base label 16.

A continuous transparent overlayer 20 may be next applied, by conventional laminating techniques, over the joined brochure blank assembly 40 and base label web 42, covering and adhering to the portions of the base label blanks 52 not covered by the brochure blank assembly 40, to the top panel 54 of the brochure blank 40, and to the remainder of the base label web 42.

Referring now to FIG. 31, the final die cutting step will now be described. In this step, the individual labels 12 may be cut to their final external dimensions by cutting through the overlayer 20, the brochure blank assembly 40 and the base label blanks 52, but not the liner 14. This die cutting step may establish the final outline of the tabs 32 as well. Stripping from the liner 14 of the excess material (i.e., material outside the outline of the label as defined by the die) yields the label assembly 10 depicted in FIG. 19.

The overlayer 20 may also be perforated, as at 62 in FIG. 31, adjacent to the fold line 30 of the brochure blank assembly 40. Such a perforation facilitates selective ready removal of the entire brochure 18 from a label 12, by grasping of the brochure and tearing of the overlayer 20 along the perforation 62. The perforation 62 may be made as part of the final die cutting step described above, by die cutting through the overlayer 20.

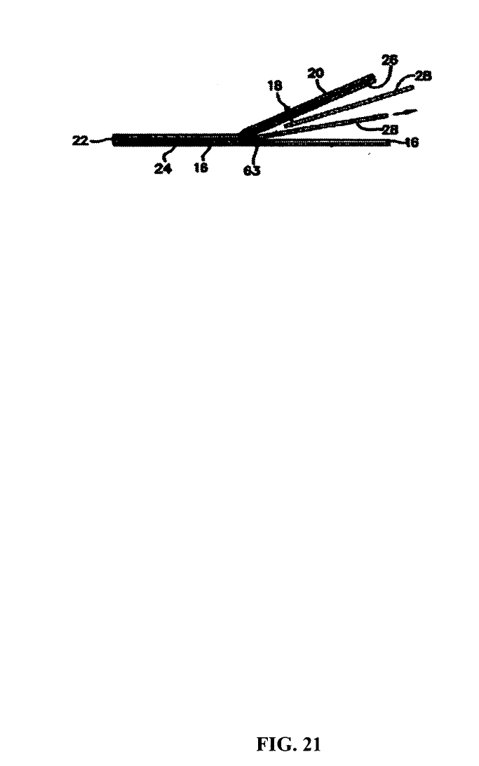

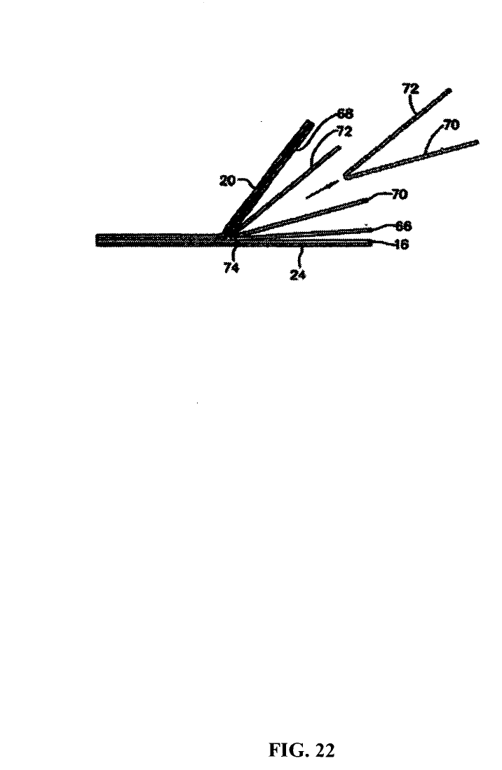

FIGS. 21 and 22 illustrate particular features of various forms of labels in accordance with the invention. In FIG. 21, there is shown in dotted line the manner in which one of the leaves of the brochure may be removed, for use as a return coupon or a source of information. For this purpose, a line of perforations 63 may be provided across the leaf 28 in a direction transverse to the leaf, to facilitate removal of the leaf. The perforation 63 may be made during printing or die cutting of the brochure blank assembly from which the brochure 18 is made.

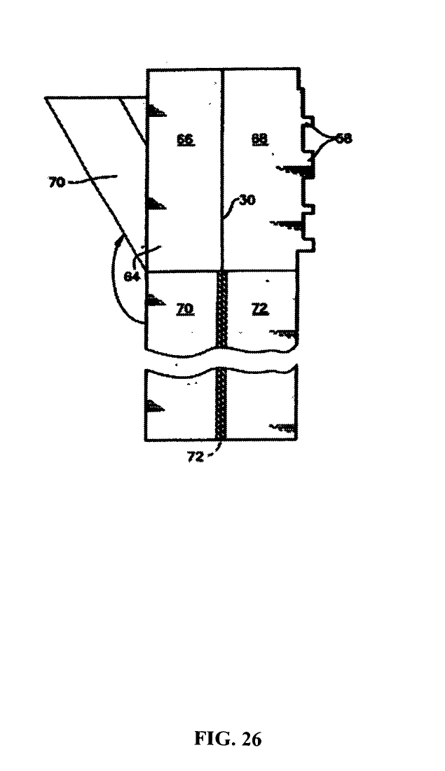

FIGS. 22 and 26 illustrate aspects of an alternative form of the invention, which provides a potential for eight pages of text within a brochure made up of four leaves. In this embodiment a brochure blank 64, as seen in FIG. 26, is so folded as to provide respective panels 66, 68, 70 and 72. The panels 70 and 72, it will be understood, may be folded behind the panels 66 and 68, and the thus-folded blank 64 thereafter used in the manner described above in connection with the brochure blank assembly 40. Final die cutting in the manner described above yields from the panels 66-72 a total of 4 leaves.

It will be appreciated that in folding the brochure blank 64, a line of glue 74 may be applied to the blank 64, as illustrated in FIG. 26, to maintain the leaves provided by the panels 70 and 72 in position relative to the other panels after the final die cutting step. The glue 74 may be applied in a conventional manner before the folding step. As is apparent from FIG. 22, with this embodiment, one pair of leaves may, if desired, be extracted from the brochure as a return coupon or informational piece.

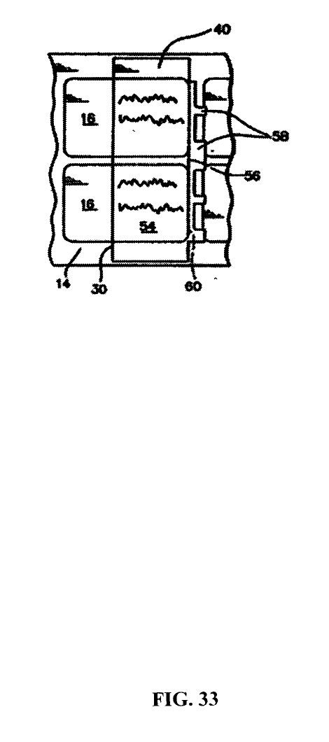

Those skilled in the art will appreciate that although the above-described embodiments of the brochure are “book-like” in the sense that they have leaves joined at a spine (defined by a fold line), it is within the purview of the invention to provide a brochure whose panels are joined by spaced parallel fold lines. Such an embodiment of the invention is seen in FIG. 33 and designated generally by reference numeral 76.

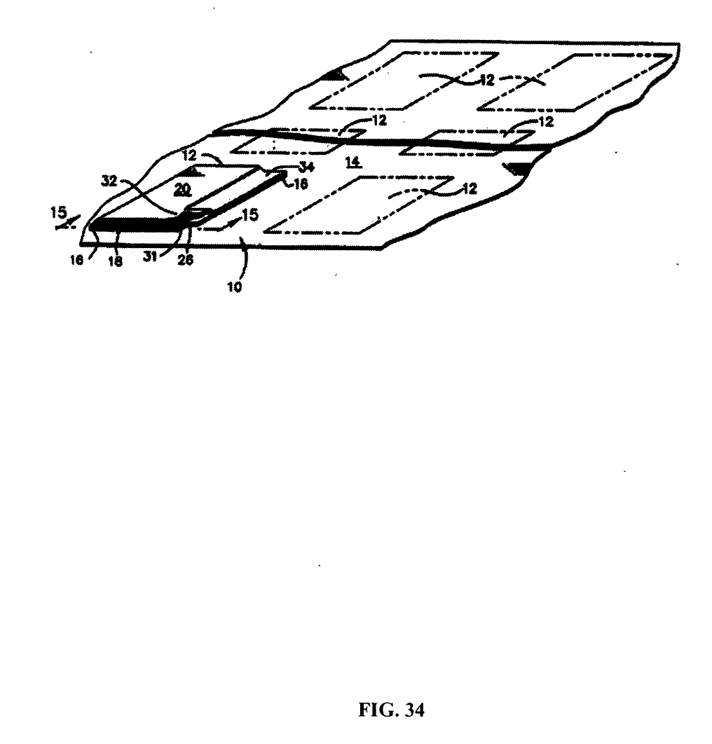

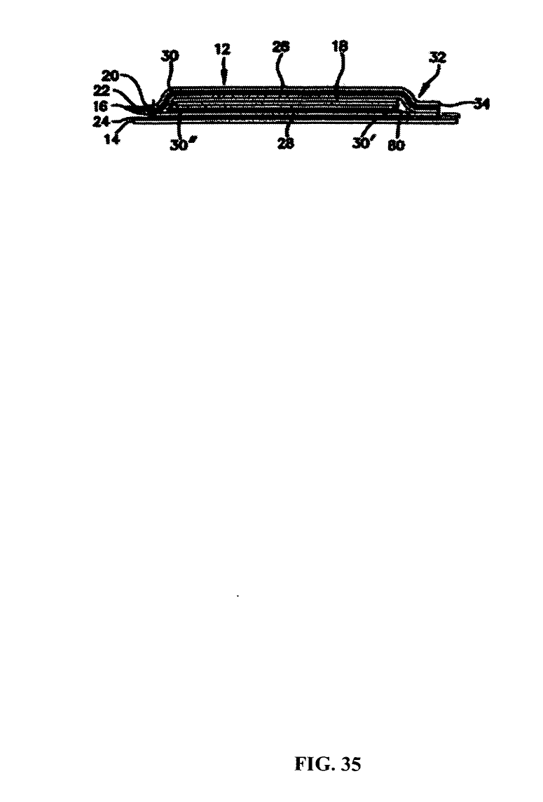

FIGS. 34 through 40 depict yet another embodiment of this invention. Referring to FIGS. 34 and 35, label 12 comprises base label 16, brochure 18 and overlayer 20. Brochure 18 may comprise any number of panels as exemplified by the seven panel construction depicted in FIGS. 34-37. Seen in FIG. 35 is adhesive layer 22 by which overlayer 20 is secured to top leaf 26 of brochure 18 and base label 16, an adhesive layer 80 which secures bottom leaf 28 of brochure 18 to base label 16, and adhesive layer 24 which releasably secures base label 16 to liner 14.

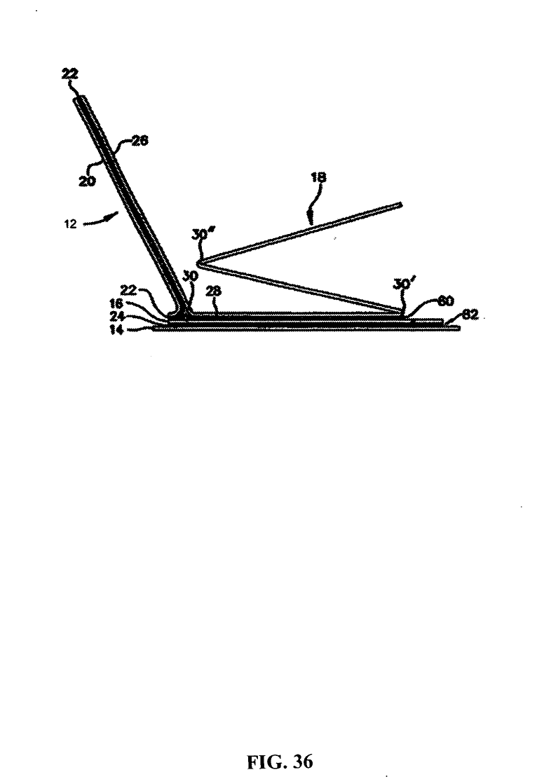

Although brochure 18 in FIGS. 34-37 is a leaflet which is formed or folded to provide seven printed surfaces or “panels,” it will be apparent to those skilled in the art that label 12 may accommodate numerous configurations of brochure 18. In the embodiment of FIGS. 34-37, fold line 30 separates leaves 26 and 28. Fold line 30 also forms an area in which the additional panels of brochure 18 may be folded (for example along fold lines 30′ and 30″ as shown in FIGS. 35 and 36 and inserted between leaves 26 and 28 when label 12 is in the closed position.

Top leaf 26 may be wider than bottom leaf 28, and thus extends further from fold line 30 than does bottom leaf 28. Additionally, a portion of top leaf 26 designated as area 32 in FIGS. 34, 35 and 37 extend beyond lateral edge 31 of base label 16 shown in FIG. 34.

As will be apparent to those skilled in the art, label 12 as depicted in FIGS. 34-37 may be affixed to containers with various cross-sections including, but not limited to, containers 38 shown in FIGS. 23 and 24. As mentioned previously, label 12 may be any label as described herein, may take any of the numerous shapes as described herein, and may be adhered to the entire surface area of container 38 or any portion of container 38, such as container 38 shown in FIG. 24. For example, label 12 of FIG. 34 may be adhered to any one of the four sides of container 38 shown in FIG. 23. Alternatively, label 12 could be adhered to any two sides and any corner of container 38.

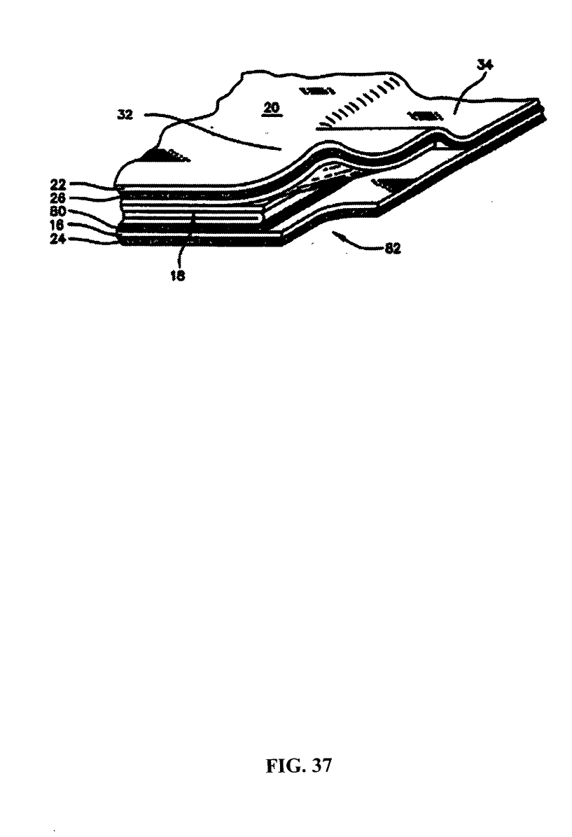

Tab 32 of label 12 depicted in FIGS. 34, 35, and 37 (shown with a corner turned upward in order to demonstrate the flexibility of tab 32) facilitates the opening of the brochure because it is interposed between leaf 26 of brochure 18 and container 38, and further, because of notched opening 82 in base label 16. When applied to container 38, relief notch 82 creates a space between leaf 26 and the substrate (such as container 38) to which label 12 is affixed. Tab 32 thus provides a convenient “handle” and an aid to gaining access to brochure 18. On the other hand, as best shown in FIG. 37, adhesive 22 present on portion 34 of overlayer 20 facilitates repeated unsealing and resealing of brochure 18 as container 38 is used.

The materials used in the construction of this embodiment of the invention depicted in FIGS. 34-37 may be the same as used in the construction of other embodiments of this invention. In addition, adhesive 80 may be any material suitable for adhering brochure 18 to base label 16 and may also be a cold glue.

Referring now to FIGS. 34 and 3840, a method of making an adhesive label assembly in accordance with the instant embodiment of label 12 will be described.

In general, the method involves the following steps, each of which will be described in greater detail below: brochure blank assembly 40 may be created by printing, cutting and folding. Brochure blank assembly 40 may be prepared in full web width. Base label 16 may be printed, also in full web width. Next, base label 16 may be die cut from base label web 42 (which, in part, forms relief notch 82) and excess waste (depicted in the accompanying figures as “W”) may be stripped from base label blanks 52, each blank ultimately providing, in the presently preferred form of the method, three base labels 16. Next, brochure blank assembly 40 may be affixed to base label blank 52 by applying adhesive 80 to base label blank 52 and joining brochure blank assembly 40 to adhesive 80. Although in this embodiment adhesive 80 may be necessary if brochure 18 is to remain affixed to base label 16, it is not necessary to use adhesive 80 if brochure 18 is to be completely removed from label 12. Overlayer 20 may then be applied over exposed liner 14, base label blank 52, and brochure blank assembly 40. Finally, base label blank 52, brochure assembly 40 and overlayer 20 may be die cut to final outline 86 of label 12, and waste “W” may be stripped to yield the final label assembly.

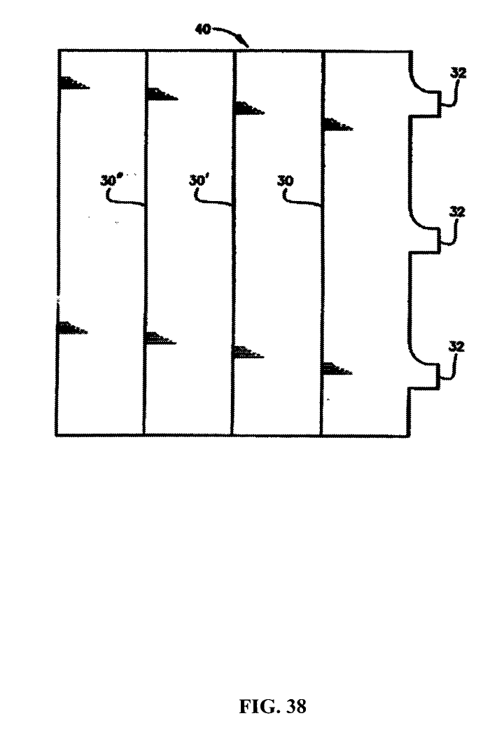

Referring now to FIG. 38, brochure blank assembly 40 may be created as follows: brochure blanks may be printed by any suitable process. In the presently preferred process, brochure blank 40 may be printed by sheet-fed offset printing in full sheets (typically about twenty-four inches wide) and which may be cut in half to form a full web width (typically about approximately twelve inches). Each full web width may contain multiple repetitions of printed matter. One form of the process may print on each full web width three brochures 18. Optionally, brochures may be printed on one or both sides of brochure blank assembly 40. The portions of brochure blank assembly 40 which, with further trimming, will ultimately form tabs 32 of the embodiment of FIGS. 34-37, may be die cut, although other techniques may occur to those skilled in the art. The full web width may then be trimmed to size and folded as desired, such as at fold lines 30, 30′ and 30″ depicted in FIG. 38.

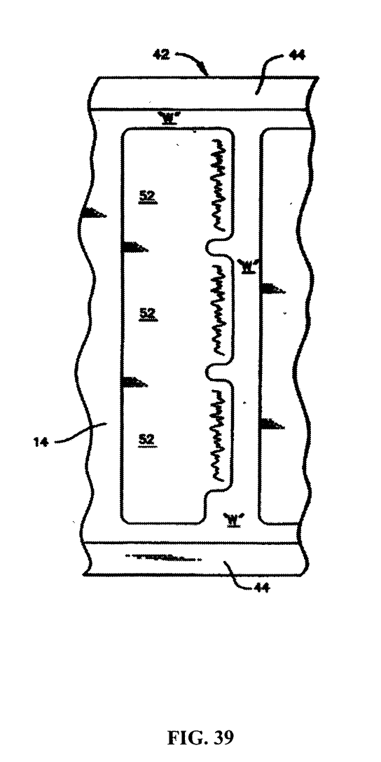

Turning now to FIG. 39, base label web 42 of this embodiment may be printed as disclosed above, except that three rather than four repetitions may be printed across base label web 24, although other repetitions may also be possible.

FIG. 39 depicts a form of base label web 42 after die cutting through base label sheet 44 (but not liner 14) to form three attached base label blanks 52. The die cutting operation of FIG. 39 provides three attached base label blanks 52, which blanks 52 may be separated in a later step in the process. The width of each blank 52 enables it to provide a base label 16 for three labels 12. Other equivalent arrangements may occur to those skilled in the art. After die cutting, the waste material “VV” around base label blanks 52 may be stripped from base label web 42.

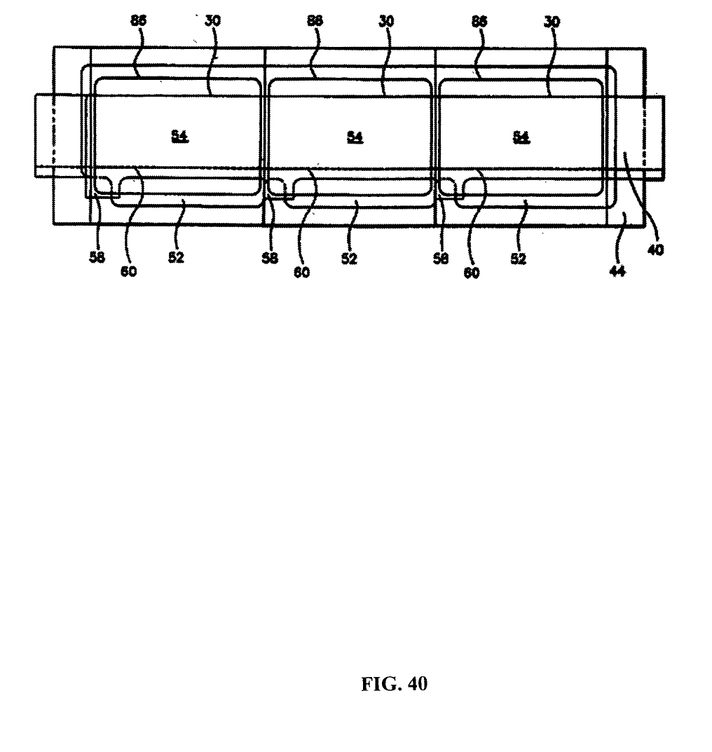

Referring now to FIG. 40, the step of joining the brochure blank assembly 40 with base label web 42 is illustrated. First, adhesive 80 is applied to a section of each label blank 52 at which section brochure blank assembly 40 may be applied to label blank 52. Adhesive 80 may be applied to base label blanks 52 in a continuous area approximately the size and shape of brochure blank assembly 40. Alternatively, adhesive 80 may be applied to the underside of brochure leaf 28.

After application of adhesive 80, brochure blank assembly 40 may be brought into juxtaposition with base label web 42 in such a way that fold 30 extends transversely with respect to base label sheet 44. It will be recognized that this operation may be automated in ways described above with respect to the embodiment of the invention described herein. Folding of brochure label 40 may be done in such a way as to provide an assembly having a top panel 54, which ultimately forms the above-mentioned top leaves 26 of brochures 18, and bottom panels 56 (not shown in FIG. 40), which ultimately forms bottom leaves 28 of brochure 18. Associated with top panel 54 may be projections 58 which, after further cutting described below, form tabs 32 associated with top leaves 26. Top panel 54, it should be understood, extends from fold line 30 a distance greater than the width of bottom panel 56, so that when brochure blank assembly 40 is positioned with respect to base label web 42, panel 54 may project beyond lateral edge 60 of what is fold 30′ such that top panel 54 may contact at least a portion of label blank 52.

A continuous transparent overlayer 20 may next be applied, by conventional laminating techniques, over joined brochure blank assembly 40 and base label web 42, covering and adhering to the portions of base label blanks 52 not covered by brochure blank assembly 40, to top panel 54 of brochure blank 40, and the remainder of the base label web 42.

The final die cutting step may be substantially as described with respect to other embodiments of this invention. In this step, individual labels 12 may be cut to the final external dimensions. This die cutting step establishes a final label outline 86 of label 12 (including tab 32) as depicted in FIG. 40. Stripping from liner 14 of excess material (i.e., material outside final label outline 86) yields label assembly 10 depicted in FIG. 34.

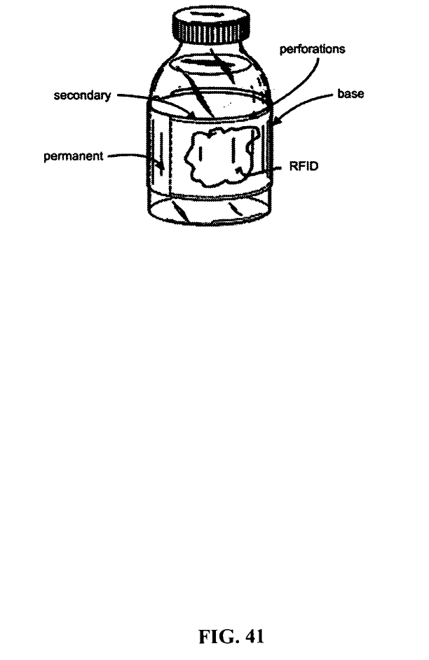

In yet another embodiment of the present invention, a radio frequency identification (RF ID) tag, or set of RF ID tags, may be incorporated into or otherwise associated with any portion of any of the label embodiments described hereinabove. For example, FIG. 41 illustrates a container having resident thereon a secondary label portion applied over at least part of a base layer label. At least a portion of the secondary label portion has included, therein or resident thereon, a RF ID tag. The RF ID tag may be any RF ID tagging methodology known to those skilled in the art, such as printing an RF ID circuit, providing a magnetic strip, or the like, and the RF ID may be active or passive.

The RF ID tag may be resident between a backside and a front ply of the secondary label portion, and as such the RF ID tag may be resident between the front side and the back side of the secondary label portion. Alternatively, such as wherein the secondary label portion comprises a single ply, the RF ID tag may be printed on, or fastened to, the single ply, and thus may be exposed at the front side or back side of the secondary label portion.

In an embodiment, at least a portion of the secondary label portion may be permanently affixed to, or may be permanently affixed immediately adjacent to, at least a portion of the base layer label, or may be partially or substantially permanently affixed to the container. A remaining portion of the secondary label portion may be removable from contact with or adjacency to the base layer label, and it is preferable that this removable portion of the secondary label portion include, in association therewith, the RF ID tag. The removable portion of the secondary label portion may be capable of being “torn away” from the permanently affixed portion of the secondary label portion, such as by the placement of the perforations discussed hereinabove, or via a non-permanently adhering adhesive, along the junction point between the permanently affixed portion of the secondary label and the removable portion of the secondary label. As discussed with respect to the label embodiments hereinabove, other portions of the removable portion may be temporarily adhered to the base layer label, or to the container, or may be at least partially deadened, so as to allow minimization of the adherence of the removable portion to or adjacent to the permanent portion of the secondary label, to the base layer label, and to the container. In an embodiment, at least a portion of the removable portion of the secondary label is deadened so as to avoid adherence of the back side of the secondary label to the base label underneath the removable portion of the secondary label, and at least a part of the RF ID tag is preferably included at that deadened portion of the secondary label.

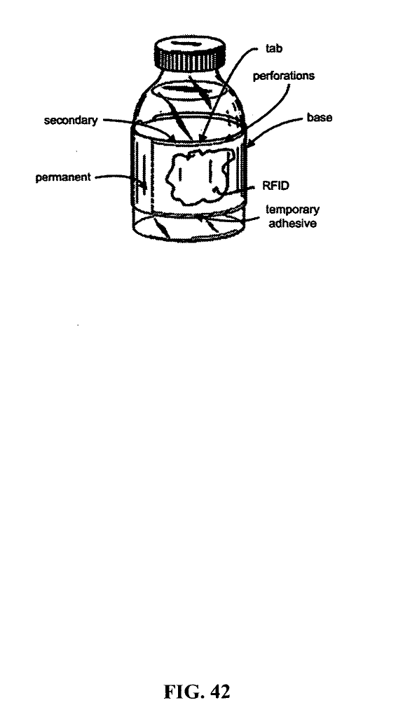

FIG. 42 illustrates an embodiment of the secondary label portion of FIG. 41 wherein the removable portion of the secondary label has, along its left and right sides, perforations that join the removable portion to the permanently affixed portion, and along the lower portion of the removable portion is illustrated a temporary adhesive that, upon tearing of the perforation, allows ease of removal of the removable portion from contact with the base label and/or the container. As illustrated, the top portion of the removable portion is substantially or entirely deadened, and may be perforated with a more robust perforation than the left and right sides, thereby at least partially providing a tab for easy grasping by the fingers, wherein grasping of the tab by the fingers and pulling downward or to one side easily removes the removable portion of the secondary label from contact with the permanently affixed portions of the secondary label. The more robust perforations provided at the tab may allow for later removal of the tab from the RF ID portion.

In an embodiment, removal of the removable portion of the secondary label may provide complete removal of the RF ID tag associated with the removable portion. Tracking of this RF ID tag may allow for tracking from the generation point, and through the traffic flow, of the container associated with the RF ID tag, until the point whereat the RF ID tag is removed. The party to whom the container is presented may then be associated with the RF ID tag, and maintenance of the removed RF ID tag at the point of removal may allow for later tracking of the party to whom the container was passed.

In an alternative embodiment, a portion of the RF ID tag may remain in contact with the base label when a portion of the RF ID tag is also removed, or the base label may have associated therewith a “sister” RF ID tag, the identification of which “sister” is mated with the RF ID tag portion removed through the removal of the removable portion of the secondary label. Such mating of RF ID tag portions, or separate secondary label and base label RF ID tags, may allow for continued tracking of, and identification of the mates of, the container even after removal of the secondary portion, and may allow for association of the container with the removed removable portion even after removal of the removable portion.

In an embodiment wherein removal of the removable portion includes complete removal of all RF ID tags, or in an embodiment wherein any remaining RF ID tags or RF ID tag portions in contact with the base label are not visible to a viewer upon removal of the removable portion, it may be preferable that the portion of the base layer label immediately beneath and adjacent to the back side of the removable portion of the secondary label may have its own similar or identical print or information, when exposed, to the print or information on front side of the removable portion of the secondary label. As such, the label information would appear to the viewer as being the same upon removal of the removable portion as before removal of the removable portion, because the base layer label portion visible upon removal of the removable portion has a similar appearance to the front side of the removable portion of the secondary label. Such an embodiment may be particularly useful in an environment, such as a pharmaceutical environment, wherein the same information must be conveyed by the label whether or not the RF ID tag label portion has been removed. Obviously, in pharmaceutical embodiments wherein relabeling occurs after removal of the RF ID tag, such as when a prescription is passed by a pharmacist to a patient, the appearance of the base layer beneath the removable portion is not of particular importance, although the ability to identify the container must be maintained if subsequent matching to a removed RF ID tag becomes necessary.

In other embodiments, the tearing away of the RF ID tag may not only provide for tracking of the container associated with the RF ID tag before removal, but may alternatively allow for tracking and verification of the portion removed as the removable portion of the secondary label, such as for playing pieces removed from containers in a contest, for example.

Those of ordinary skill in the art may recognize that many modifications and variations of the present invention may be implemented without departing from the spirit or scope of the invention.

1. A label suitable for attachment to an object, said label comprising:
a base label portion;
a secondary label portion at least semi-permanently affixed to at least a portion of the base layer label, wherein the secondary label portion comprises a removable portion that is at least partially removable from the semi-permanent affixation to the base label portion, and wherein the removable portion includes at least one RF ID tag portion;
wherein at least a portion of the base label portion exposed upon removal of the removable portion comprises a printing of equivalent information to an external face of the removable portion prior to removal.

2. The label of claim 1, wherein the semi-permanent affixation comprises a plurality of perforations.

3. The label of claim 1, wherein the semi-permanent affixation comprises a non-permanently adhering adhesive.

4. The label of claim 1, wherein the semi-permanent affixation is resident along a junction point between a permanently affixed portion of the secondary label and the removable portion.

5. The label of claim 1, wherein the base label portion comprises at least one deadened portion.

6. The label of claim 1, wherein the secondary label portion comprises at least one deadened portion on a non-external face of the secondary label portion.

7. The label of claim 1, wherein the removable portion comprises at least one deadened portion.

8. The label of claim 7, wherein at least a portion of the RF ID tag portion is included at the deadened portion.

9. The label of claim 1, wherein the semi-permanent affixation comprises a plurality of perforations, and at least one semi-permanent adhesive strip applied perpendicularly to the plurality of perforations.

10. The label of claim 1, wherein the removable portion comprises four edges, and wherein the semi-permanent affixation along two of the edges is perforations, along one of the edges is deadened, and along one of the edges is semi-permanently adhered.

11. The label of claim 10, wherein the deadened edge of the semi-permanent affixation further comprises a pull tab.

12. The label of claim 11, wherein the pull tab further comprises robust perforations requiring an application of additional force for removal over removal force required by the perforations along two of the edges.

13. The label of claim 1, wherein removal of the removable portion of the secondary label provides complete removal of the RF ID tag portion.

14. The label of claim 1, wherein removal of the removable portion of the secondary label provides partial removal of the RF ID tag portion.

15. The label of claim 14, wherein a remaining portion of the RFID tag portion comprises a mated portion to the partially removed RF ID tag portion.

16. A method of forming a label suitable for attachment to an object, comprising:
providing a permanently adhering base label portion;
semi-permanently affixing a removable portion of a secondary label portion at least to at least a portion of the base layer label;
permanently affixing a non-removable portion of a secondary label portion to a at least a portion of the base layer label;
applying a first RF ID tag to a non-external face of the removable portion;
applying a mated RF ID tag of the first RF ID tag on the base label portion.
